(19) United States
(12) Patent Application Publication
(10) Pub. No.: US 2013/0216373 A1
(43) Pub. Date: Aug. 22, 2013

(54) FIXING APPARATUS FOR FAN

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/407,780

(22) Filed: Feb. 29, 2012

(30) Foreign Application Priority Data
Feb. 20, 2012 (CN) 201210038121.6

(51) Int. Cl. F04D 29/64; F04D 29/52; H05K 7/14

(52) U.S. Cl. 415/213.1; 248/220.31

(57) ABSTRACT

A fixing apparatus for a fan includes a bottom wall, and a fixing member for fixing the fan. A first fixing portion and a second fixing portion are formed on the bottom wall. The fixing member includes a plate defining a through hole, and an extension piece extending from a side of the board. The through hole includes a first hole and a second hole communicating with the first hole. The second hole is less than the first hole in size. The extension piece defines a side cutout. The fixing member is slidably mounted to the bottom wall. The first fixing portion extends through the first hole and engages in the second hole, and the second fixing portion engages and is retained by the cutout.

### BACKGROUND

1. Technical Field

The present disclosure relates to an apparatus for fixing a fan.

2. Description of Related Art

Large electronic devices use fans to cool electronic components installed therein. In related art, fans are usually mounted in the electronic device by a plurality of screws, which makes it difficult and time-consuming to replace or remove the fans for repair.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fixing apparatus together with a number of fans.

FIG. 2 is a partly assembled, isometric view of the fixing apparatus of FIG. 1.

FIG. 3 is an assembled, isometric view of the fixing apparatus of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

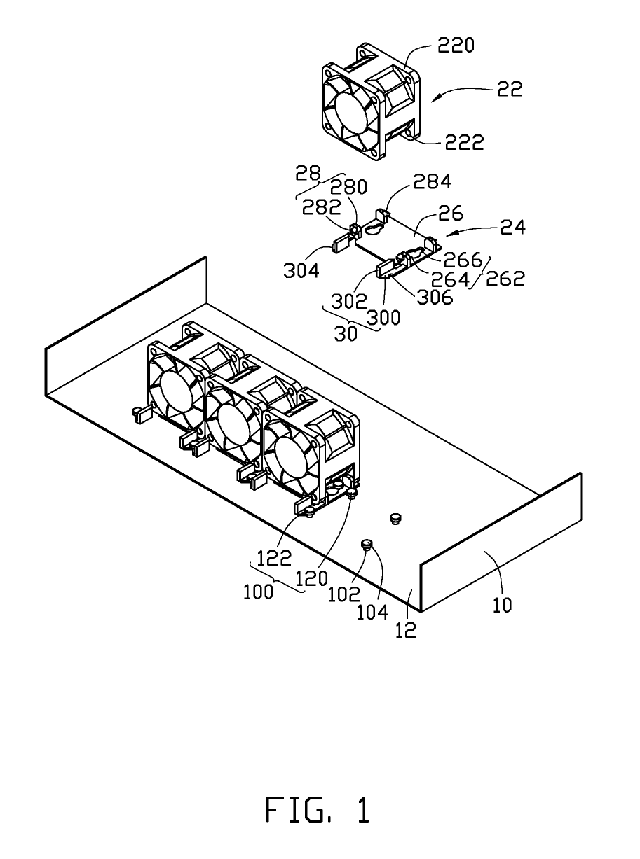

Referring to FIG. 1, an exemplary embodiment of a fixing apparatus for a fan 22 includes a chassis 10 and a fixing member 24 detachably mounted in the chassis 10. The fan 22 has a flat front-facing surface and a flat rear-facing surface (together referred to as spaced boards 220). Each board 220 defines four corner holes 222.

The chassis 10 includes a bottom wall 12. A group of fixing portions 100, in a particular arrangement, is formed on the bottom wall 12. The group of fixing portions 100 includes two first fixing portions 120 and two second fixing portions 122 positioned in tandem with the first fixing portions 120. Each of the first and second fixing portions 120 and 122 includes a neck 102 perpendicularly extending up from the bottom wall 12, and a head 104 formed on a top end of the neck 102 opposite to the bottom wall 12. The diameter of the head 104 is substantially greater than the diameter of the neck 102.

The base 24 includes a rectangular plate 26, a protrusion 28 extending up from each of the four corners of the plate 26, and two latches 30 extending from opposite ends of a side of the plate 26. Two through holes 262 are defined in the plate 26. Each through hole 262 aligns with a latch 30, and the distance between the two through holes 262 is equal to the distance between the two fixing portions 120, or to the distance between the two fixing portions 122 as circumstances require. Each through hole 262 includes a first hole 264 adjacent to a latch 30, and a second hole 266 communicating with the first hole 264 and further away from the latch 30. The size of the first hole 264 is greater than the size of the second hole 266. Each protrusion 28 includes a positioning piece 280 extending up from the plate 26, and a pin 282 protruding out from a side of the positioning piece 280 away from the corresponding through hole 262. A top surface 284 of each pin 282 slantingly extends down from a top of the positioning piece 280 toward a distal end of the pin 282 opposite to the positioning piece 280.

Each latch 30 includes an extension piece 300 extending out from the side of the plate 26, and an operation portion 302 extending up from an inner side of the extension piece 300 adjacent to the other latch 30. A semicircular cutout 306 is defined in an outer side of the extension piece 300 opposite to the operation portion 302. An end surface 304 of each extension piece 300 away from the plate 26 slantingly extends from the operation portion 302 towards the cutout 306.

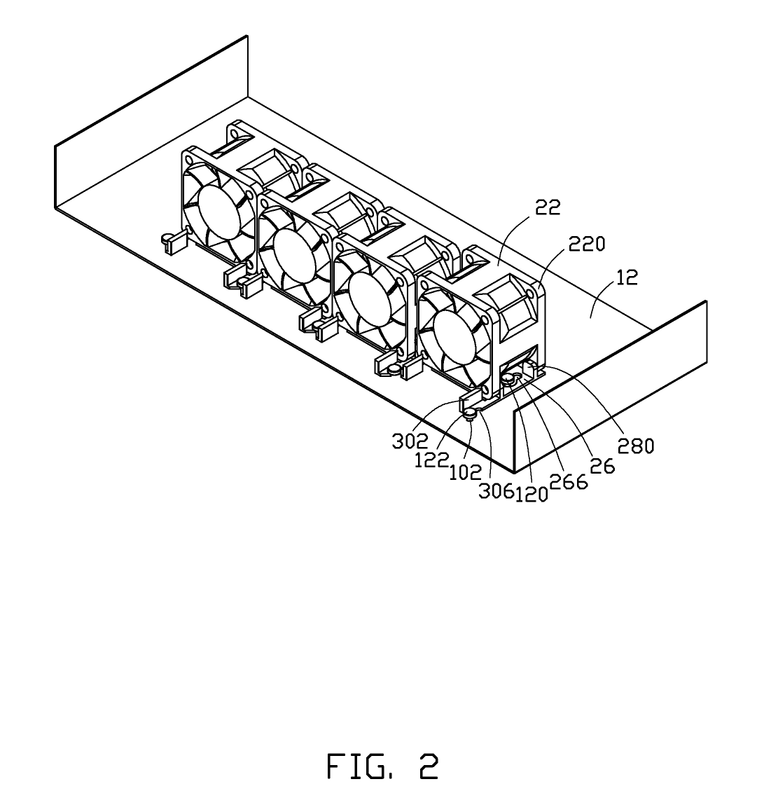

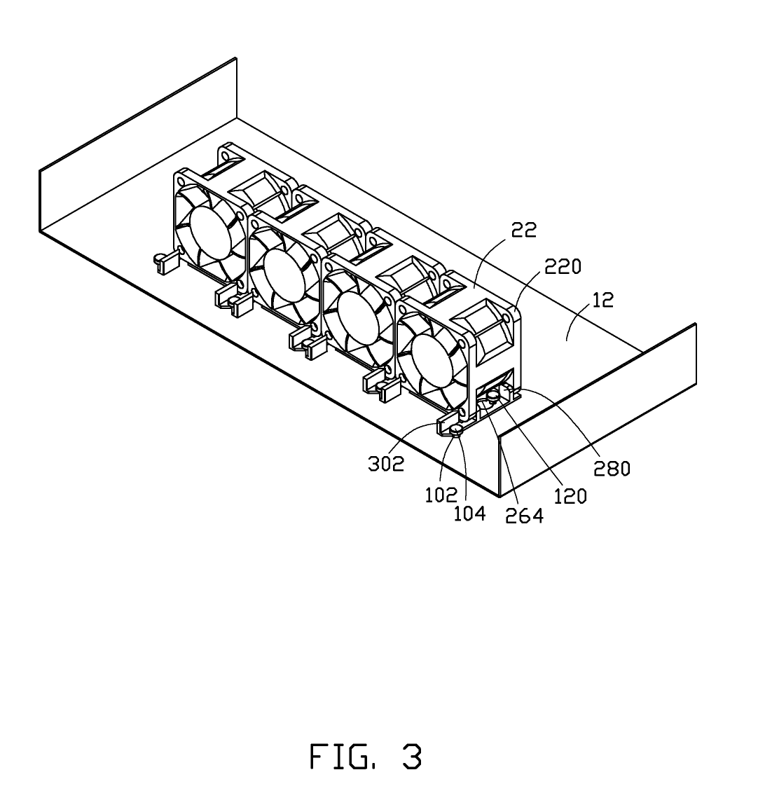

Referring to FIGS. 2 and 3, in assembling the fan 22 to the fixing member 24, the fan 22 is attached to the fixing member 24. The spaced boards 220 are supported and held in place on the pins 282. The fan 22 is moved down to abut the top surfaces 284, causing the positioning pieces 280 to deform towards the through holes 262. As the spaced boards 220 are pushed past the top surfaces 284, the pins 282 are positioned in a space between the boards 220 and then engaged in the corner holes 222.

In installing the fixing member 24 to the chassis 10, the fixing member 24 is put on the bottom wall 12. The first holes 264 are manipulated over the first fixing portions 120. The second fixing portions 122 are then adjacent to the end surfaces 304. The fixing member 24 is then slid to allow the necks 102 of the second fixing portions 122 to slidably abut the end surfaces 304, thereby deforming the extension pieces 300 towards each other. After the necks 102 pass the end surfaces 304, the extension pieces 300 self-restore to make sidewalls in which the cutouts 306 are defined snap back against the necks 102, and the heads 104 of the second fixing portions 122 then abut the top surfaces of the extension pieces 300. The necks 102 of the first fixing portions 120 enter the second holes 266. The heads 122 of the first fixing portions 120 abut the top surface of the plate 26 and are thus captive.

In uninstalling the fixing member 24 together with the fan 22, the operation portions 302 are deformed toward each other with finger pressure, to disengage the necks 102 of the second fixing portions 122 from the cutouts 306. Then the fixing member 24 together with the fan 22 can be slid back to disengage the first fixing portions 120 from the second holes 266.

In another embodiment, the group of fixing portions 100 may just include only one first fixing portion 120 and only one second fixing portion 122, and the fixing member 24 forms only one latch 30.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A fixing apparatus for fixing a fan having two spaced boards, comprising:
a bottom wall forming a first fixing portion and a second fixing portion; and
a fixing member comprising a plate to fix the fan, and an extension piece extending out from a side of the plate, the plate defining a through hole having a first hole and a second hole communicating with the first hole, wherein a size of the first hole is greater than a size of the second hole; the extension piece defines a cutout in a first side of the extension piece;
wherein the fixing member is slidably mounted on the bottom wall, the first fixing portion is extended through the first hole and then engaged in the second hole, the second fixing portion is engaged in the cutout.

2. The fixing apparatus of claim 1, wherein four protrusions extend up from the plate, each protrusion comprises a positioning piece perpendicularly extending up from the plate and a pin protruding from an outer surface of the positioning piece, the pins of the protrusions are positioned in a space between the boards and engage with spaced boards of the fan.

3. The fixing apparatus of claim 2, wherein a top surface of each pin slantingly extends down from a top of the corresponding positioning piece toward a distal end of the pin opposite to the positioning piece.

4. The fixing apparatus of claim 1, wherein an operation portion extends up from a second side of the extension piece opposite to the cutout.

5. The fixing apparatus of claim 4, wherein an end surface of the extension piece opposite to the plate slantingly extends from the operation portion toward the cutout.

6. The fixing apparatus of claim 1, wherein each of the first and second fixing portions comprises a neck extending from the bottom wall and a head extending from a top end of the neck opposite to the bottom wall, a diameter of the head is greater than a diameter of the neck, the head of the first fixing portion is blocked by a top surface of the plate in response to the corresponding neck enters the second hole, the head of the second fixing portion is blocked by a top surface of the extension piece.

7. The fixing apparatus of claim 1, wherein the first hole is adjacent to the extension piece, the second hole is away from the extension piece.

8. A fan assembly, comprising:
a bottom wall forming a first fixing portion and a second fixing portion;
a fan; and
a fixing member comprising a plate to fix the fan, and an extension piece extending out from a side of the plate, the plate defining a through hole having a first hole and a second hole communicating with the first hole, wherein a size of the first hole is greater than a size of the second hole; the extension piece defines a cutout in a first side;
wherein the fixing member is slidably mounted on the bottom wall, the first fixing portion is extended through the first hole and then engaged in the second hole, the second fixing portion is engaged in the cutout.

9. The fan assembly of claim 8, wherein the fan comprises two opposite boards, each board defines four two corner holes in a lower side of the board, four protrusions extend up from the plate, each protrusion comprises a positioning piece perpendicularly extending up from the plate and a pin protruding from an outer surface of the positioning piece, the pins of the protrusions are positioned in a space between the boards and engage in the corresponding corner holes.

10. The fan assembly of claim 9, wherein a top surface of each pin slantingly extends down from a top of the corresponding positioning piece toward a distal end of the pin opposite to the positioning piece.

11. The fan assembly of claim 8, wherein an operation portion extends up from a second side of the extension piece opposite to the cutout.

12. The fan assembly of claim 11, wherein an end surface of the extension piece opposite to the plate slantingly extends from the operation portion toward the cutout.

13. The fan assembly of claim 8, wherein each of the first and second fixing portions comprises a neck extending from the bottom wall and a head extending from a top end of the neck opposite to the bottom wall, a diameter of the head is greater than a diameter of the neck, the head of the first fixing portion is blocked by a top surface of the plate in response to the corresponding neck enters the second hole, the head of the second fixing portion is blocked by a top surface of the extension piece.

14. The fan assembly of claim 8, wherein the first hole is adjacent to the extension piece, the second hole is away from the extension piece.
